(19) United States
(12) Patent Application Publication
(10) Pub. No.: US 2026/0319390 A1
(43) Pub. Date: Oct. 15, 2026

(54) DATA AND RULE BASED HYBRID SAMPLING FOR LITHOGRAPHY ALIGNMENT MARKS

(71) Applicant: KLA Corporation, Milpitas, CA (US)

(72) Inventors: Onur Nihat Demirer, Tomball, TX (US); Robert Hollingsworth, Portland, OR (US)

(21) Appl. No.: 19/176,083

(22) Filed: Apr. 10, 2025

(51) Int. Cl. G03F 9/00; H01L 21/68

(52) U.S. Cl. CPC G03F 9/7046; G03F 9/7007; G03F 9/7092; H10P 72/57

(57) ABSTRACT

Methods and systems for determining information for alignment marks on a wafer for use in a lithography process are provided. One method includes selecting alignment marks on a wafer for alignment of the wafer to a mask during a lithography process. The selecting includes generating an initial sample of a predetermined number of alignment marks by rule based sampling of the alignment marks on the wafer. For an alignment mark in the initial sample, the selecting also includes selecting the alignment mark or a different alignment mark in a subset of the alignment marks on the wafer closest to the alignment mark by data based sampling of the alignment mark and the subset of the alignment marks. In this manner, the embodiments perform rule based sampling followed by data based sampling.

### BACKGROUND OF THE INVENTION

### 1. Field of the Invention

This invention generally relates to methods and systems for determining information for alignment marks on a wafer for use in a lithography process. Certain embodiments relate to methods and systems for data and rule based hybrid sampling for lithography alignment mark sampling.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a photomask to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

In most modern lithography scanners (or any exposure tools that expose a resist on a wafer to a pattern of light that passes through or is reflected from a mask), the wafer processing can be divided into 2 steps. The first step is alignment. As the name implies, this step is performed to “align” the scanner stage and lens to the wafer. By measuring a number of alignment marks on the wafer, the scanner can map out the exposure grid it needs to follow. The second step is exposure. At this step, the scanner exposes fields on the wafer with the pattern that is contained in the reticle/mask, thus transferring the required pattern onto the photoresist.

The amount, location, and quality of measurements of these alignment marks are critical to the accuracy of lithography. An ideal alignment system will print the current layer exactly on top of the previous layer. Any imperfection in this system will show itself as a misregistration between current layer and previous layer, commonly referred to an “overlay” error. These overlay errors, along with other critical dimension (CD) errors, are what determine the product yield.

Alignment mark sampling is generally performed to select how many and which alignment marks are measured in the alignment step of lithography. The challenges in scanner alignment sampling can be summarized, at least in part, as follows. The number of alignment marks that can be measured is substantially limited due to scanner throughput requirements. For example, in dual stage lithography scanners, one stage performs alignment while the other exposes, and the alignment should not take longer than exposure, which would reduce throughput and increase cost of ownership. In another example, alignment marks are susceptible to process induced damage, especially in wafer edge regions. Therefore, measurements in these regions may need to be avoided. The amount of target damage and its effect varies greatly from layer-to-layer and product-to-product. On the other hand, measuring the edge regions is critical for alignment model stability. Whenever spatial modeling is performed, the sample plan should cover the full modeling domain, especially the edge regions. An additional problem in currently used alignment mark sampling is finding a sample plan that results in the closest scanner corrections to full map measurement. However, for the alignment sampling, a sample plan that results in the most stable overlay error is needed. As such, cross domain analysis is needed in optimization (to simulate the effect of changing alignment sampling on the overlay feedback control system).

Most alignment mark sampling methods and systems fall into one of two general categories: data based alignment sampling or rule based alignment sampling. Data based alignment sampling is performed with alignment data only (does not simulate the alignment effect on overlay) and selects a subsample of alignment marks that give the closest scanner corrections to full map alignment (full map means all possible alignment marks are measured). The algorithms are usually based on a hill climbing approach. This approach may include initializing with N randomly selected alignment marks (N is the sample size). One of the randomly selected marks may then be picked and replaced with one of the marks that have not been randomly selected. The modeled corrections are evaluated and compared to full map corrections (i.e., corrections that would be achieved if every alignment target on the wafer is measured) for each case. Another mark is selected, and the steps described are performed for that newly selected mark. These steps may be performed in a loop if the corrections do not get closer to full map anymore.

Rule based alignment sampling methods do not rely on any data from the physical wafer, but generate a sample plan for a given alignment model and full map definition. Instead of directly evaluating the accuracy of scanner corrections, like a data based approach, this method instead relies on a heuristic function that includes a weighted combination of multiple cost functions such as normalized model uncertainty, uniformity, edge avoidance, and scan up/scan down balance. The optimization steps are similar to data based sampling, but the cost function evaluated at each iteration is replaced by rule based metrics.

For the normalized model uncertainty, even without data, a normalized model uncertainty can be calculated, which gives a measure of how much the model amplifies or attenuates measurement variations at any point on the wafer. This metric makes sure more samples are placed at “inflection points” of models. In other words, more samples are placed in regions where the models are the least stable. In terms of uniformity, each alignment measurement is assumed to be a point charge, and the total energy state of the sample plan is calculated. The least energy state corresponds to the highest uniformity. This metric makes sure that every region on the wafer is properly covered. For edge avoidance, rough rules of thumb can be defined like “avoid sampling outside a radius of 135 mm” to avoid edge region target damage. In scan up/scan down balance, lithography scanners expose some fields while scanning up and others while scanning down. It is important to measure each roughly the same number of times, so a scan direction imbalance metric is introduced.

Each of the currently used optimization approaches have their unique disadvantages. For data based alignment sampling, one disadvantage is that optimization speed is usually much lower than rule based approaches (minutes vs seconds). Another disadvantage of this approach is that it needs relatively large data collection to provide high production volume (or high volume manufacturing (HVM)) worthy results. Data based sampling also tends to overoptimize for the state of the process within the optimization set and is thus more negatively affected by process changes. More importantly, currently used data based optimization methods rely on full map alignment measurements as a “best case” reference, but it is not always the optimal reference to use. For example, measuring all possible alignment marks might result in the lowest modeling error on the alignment side, but if some region on the wafer has target damage and alignment measurements do not correlate with overlay in that region, more stable overlay can be achieved if that location is not measured. This insight is only possible if the effect of alignment sample plan changes on overlay at each iteration is considered, but this makes performance an even bigger problem (hours for optimization).

In general, rule based sampling optimization methods work really well when sample size is large enough that no single measurement location is critical for modeling. For example, when selecting 100 or more points for overlay measurement and modeling, rule based sample plans work very well. However, when sample size is around 10-50, the heuristics mentioned above are not enough by themselves to perform optimization. By definition, rule based alignment sampling algorithms are data blind, which is a deal breaker when process induced target damage cannot be easily characterized by rules such as edge avoidance. Two measurements targets that are in neighboring fields substantially close to each other will show substantially small heuristic differences, but can result in significantly different overlay.

Accordingly, it would be advantageous to develop methods and/or systems for determining information for alignment marks on a wafer for use in a lithography process that do not have one or more of the disadvantages described above.

### SUMMARY OF THE INVENTION

The following description of various embodiments is not to be construed in any way as limiting the subject matter of the appended claims.

One embodiment relates to a system configured for determining information for alignment marks on a wafer for use in a lithography process. The system includes a computer system configured for selecting alignment marks on a wafer for alignment of the wafer to a mask during a lithography process. The selecting includes generating an initial sample of a predetermined number of alignment marks by rule based sampling of the alignment marks on the wafer. For at least one of the alignment marks in the initial sample, the selecting also includes selecting the at least one of the alignment marks or a different alignment mark in a subset of the alignment marks on the wafer closest to the at least one of the alignment marks by data based sampling of the at least one of the alignment marks and the subset of the alignment marks. The selecting further includes storing information for the selected at least one of the alignment marks or the selected different alignment mark in information for the selected alignment marks on the wafer for use in the alignment of the wafer to the mask during the lithography process. The system may be further configured as described herein.

Another embodiment relates to a computer-implemented method for determining information for alignment marks on a wafer for use in a lithography process. The method includes the steps described above. The steps are performed by a computer system. The method may be performed as described further herein. The method may include any other step(s) of any other method(s) described herein. The method may be performed by any of the systems described herein.

Another embodiment relates to a non-transitory computer-readable medium storing program instructions executable on a computer system for performing a computer-implemented method for determining information for alignment marks on a wafer for use in a lithography process. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Other objects and advantages of the invention will become apparent upon reading the following detailed description and upon reference to the accompanying drawings in which:

FIG. 1 is a block diagram illustrating an example of a system configured for aligning a wafer during a lithography process and monitoring and controlling overlay of patterns printed on the wafer during the lithography process;

FIG. 2 is a flow chart illustrating one embodiment of generating an initial sample of a predetermined number of alignment marks by rule based sampling of the alignment marks on the wafer;

FIG. 3 is a flow chart illustrating one embodiment of selecting a first alignment mark or a different alignment in a subset of alignment marks on a wafer closest to the first alignment mark by data based sampling of the first alignment mark and the subset of the alignment marks;

FIG. 4 is a schematic diagram illustrating an embodiment of a combined cost function that can be used in the data based sampling embodiments described herein and plan views of examples of wafer maps showing the positions of alignment marks selected with purely data based sampling, purely rule based sampling, and a combination of rule and data based sampling; and

FIG. 5 is a block diagram illustrating one embodiment of a non-transitory computer-readable medium storing program instructions executable on a computer system for performing one or more of the computer-implemented methods described herein.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

The embodiments described herein generally relate to systems and methods for determining information for alignment marks on a wafer for use in a lithography process. Certain embodiments relate to data and rule based hybrid sampling algorithms, systems, methods, etc. for lithography scanner alignment mark sampling. The embodiments described herein are called hybrid approaches because they aim to make use of the strengths of both data based and rule based sampling approaches, while at the same time taking data based optimization further by including cross-domain effects simulation (alignment effect on overlay). The embodiments aim to solve at least some of the sampling problems of currently used methods and systems for determining how many alignment marks to measure and where. The data and rule based hybrid approaches that are introduced herein advantageously use the benefits of both approaches and provide the best alignment sampling that results in the most stable overlay errors, which can be corrected well by an overlay feedback control system.

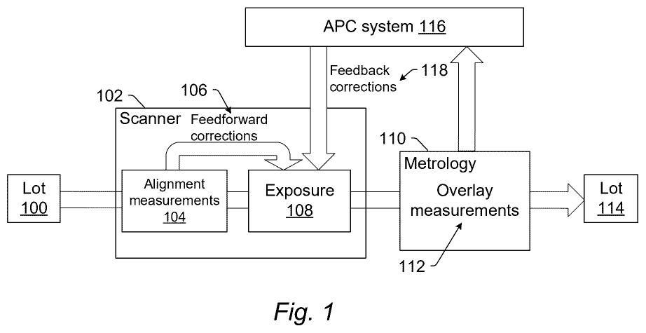

In most modern lithography exposure tools referred to herein simply as “scanners” (e.g., scanner 102 shown in FIG. 1), lot 100 of wafers may be loaded into the scanner, e.g., via a lithography track tool (not shown in FIG. 1), and then processed in two steps, alignment measurements 104 and exposure 106. The alignment step aligns the scanner stage and lens to the wafer thereby aligning the wafer to the mask or reticle used to print patterns on the wafer in the lithography process. By measuring a number of alignment marks on the wafer, the scanner can map out the exposure grid it needs to follow so that the patterns are printed in the correct locations on the wafer. In other words, results of the alignment measurements can be used to determine feedforward corrections 106 for the exposure. At the exposure step, the scanner exposes fields on the wafer with the pattern that is contained in the reticle/mask, thereby transferring the desired pattern onto the photoresist.

The amount, location, and quality of measurements of the alignment marks are critical to the accuracy of the lithography. An ideal alignment system prints the current layer on the wafer exactly on top of the previous layer on the wafer. Any imperfection in this system will show itself as a misregistration between the current and previous layers, commonly referred to as “overlay” error. These overlay errors, along with other critical dimension (CD) errors, are what determines the product yield. Subsequent to exposure, overlay errors may be measured by overlay metrology tool 110 thereby producing overlay measurements 112. The required corrections are fed back to the scanner as “process corrections.” For example, the overlay measurements may be sent to advanced process control (APC) system 116, which may use the overlay measurements to generate feedback corrections 118, which are sent back to scanner 102 to make adjustments during exposure 108 of the next or subsequent wafers.

In this manner, the alignment system within the scanner and the overlay controller system work in concert to minimize the overlay error between layers of a semiconductor device. In control terminology, the alignment system performs a “feedforward” control, predicting the corrections needed at time of exposure by alignment measurements, and the overlay control system performs a “feedback” control, calculating the corrections needed on top of alignment corrections for the next lot exposure, based on the errors of the alignment system observed during the previous exposures. After overlay measurements, the exposed and measured wafers, lot 114, may be released to other fabrication process steps like etch, deposition, chemical mechanical polishing (CMP), etc.

The system includes a computer system (e.g., computer system 504) shown in FIG. 5 configured for selecting alignment marks on a wafer for alignment of the wafer to a mask during a lithography process. This computer system (as well as other computer systems described herein) may also be referred to herein as computer subsystem(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer system, the different computer systems may be coupled to each other such that images, data, information, instructions, etc. can be sent between the computer systems. For example, computer system 504 may be coupled to another computer system (not shown) such as may be included in APC system 116 or scanner 102 shown in FIG. 1 by any suitable transmission media, which may include any suitable wired and/or wireless transmission media known in the art.

Two or more of such computer systems may also be effectively coupled by a shared computer-readable storage medium, e.g., computer-readable medium 500 shown in FIG. 5. Computer system 504 may also not be coupled to any of the tools described herein. In this manner, the computer system may be a stand alone type computer system, which may be configured to perform one or more steps described herein.

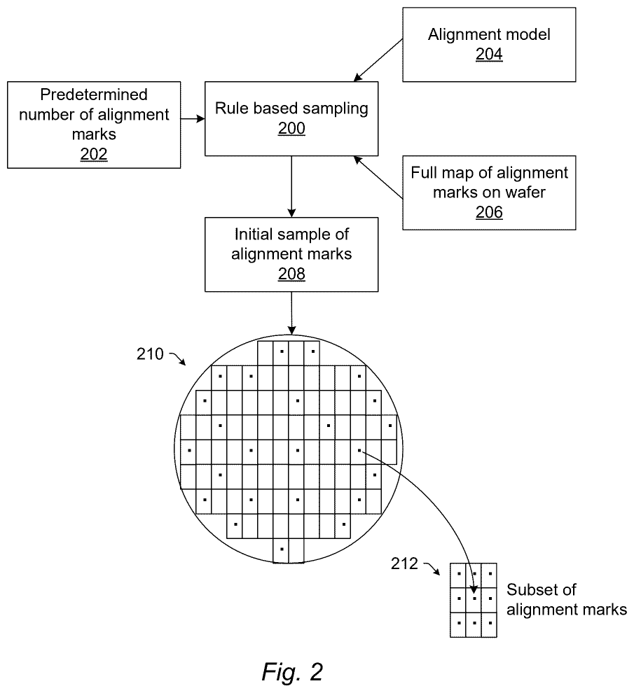

Selecting the alignment marks on the wafer for use in the lithography process includes generating an initial sample of a predetermined number of alignment marks by rule based sampling of the alignment marks on the wafer. For example, as shown in FIG. 2, one input to rule based sampling 200 is predetermined number of alignment marks 202, and rule based sampling 200 may generate initial sample of alignment marks 208. This rule based sampling step is performed to generate a sample plan that forms the anchor for the second sampling step of the embodiments, which is data based enhancement.

Information generated by rule based sampling for the initial sample of alignment marks may include any information that can be used to identify which of the alignment marks on the wafer are included in the initial sample such as alignment mark identity, identity of the fields in which the alignment marks in the initial sample are located, locations of the alignment marks in the initial sample with respect to the fields, wafer, etc. The information for the alignment marks in the initial sample may also include (or be used to generate) wafer map 210 that shows all the fields on the wafer and dots indicating the locations of alignment marks selected to be included in the initial sample.

As shown in FIG. 2, alignment marks in fewer than all of the fields on the wafer are selected to be included in the initial sample. In other words, the number of alignment marks in the initial sample may be less than the number of fields on the wafer. In addition, not more than one alignment mark may be selected in any one of the fields as shown in wafer map 210, which may be the case when there is only one alignment mark per field for lithography alignment. However, if there is more than one alignment mark per field, say alignment mark A and alignment mark B, the embodiments described herein may perform sampling for both alignment marks A and B separately thereby generating different alignment mark samples. In another alternative, if there is more than one alignment mark per field as described herein, the embodiments described herein may perform sampling for both alignment marks A and B together thereby generating a single alignment mark sample that includes alignment marks having one or more different characteristics (e.g., within field position, alignment mark patterns, alignment mark size, etc.).

The term “field” as used herein is generally defined as any repeating patterned area on the wafer that is printed in a lithography process. In general, each field that is printed in a lithography process includes an alignment mark (or more than one alignment mark in more advanced scenarios) so that is can be aligned to the field underlying it. The fields may have different characteristics such as dimensions depending on, for example, characteristics of the devices being fabricated on the wafer.

In one embodiment, input to the rule based sampling does not include data for the alignment marks on the wafer generated by a tool that performed a process on the wafer, and input to the data based sampling described further herein includes the data. For example, rule based alignment sampling does not rely on any data from the wafer, i.e., data measured or generated by performing a process (like a metrology process) on a physical wafer. In other words, rule based sampling may be performed based on a priori information about the wafer, the lithography tool, the alignment performed by the lithography tool, etc., but not any output, data, measurements, images, etc. generated by a tool that performs a process on the physical wafer. Such output, data, etc. generated with the physical wafer may instead only be used in the data based sampling portion of the hybrid approaches described herein.

In another embodiment, the rule based sampling generates the initial sample for a predetermined alignment model and a definition of a full map of the alignment marks on the wafer. For example, as shown in FIG. 2, the inputs to rule based sampling 200 may include alignment model 204 and full map of alignment marks on wafer 206. The alignment model may include any of the alignment models described herein and may vary depending on the scanner configuration, the alignment model(s) that are used by the lithography tool, etc. Generally, the alignment model used by rule based sampling is preferably the same alignment model that will be used by the scanner for the wafer. Therefore, the computer system may acquire the predetermined alignment model from a scanner or a computer-readable storage medium in which information for the alignment model that will be used by a scanner for the wafer is stored. The definition of the full map of the alignment marks on the wafer may be acquired from information about the layout of the wafer and the locations of the alignment marks within the fields on the wafer. The computer system may acquire the full map definition for the alignment marks in any suitable manner, e.g., from a computer-readable storage medium in which information for the alignment mark locations on the wafer is stored.

In a further embodiment, the rule based sampling is performed with a heuristic function that includes a weighted combination of multiple cost functions. The heuristic function may include any suitable heuristic function currently used for alignment mark rule based sampling. The multiple cost functions may include, for example, normalized model uncertainty, uniformity, edge avoidance, and scan up/scan down balance. Even without data, the normalized model uncertainty can be calculated, which gives a measure of how much the model amplifies or attenuates measurement variations at any point on the wafer. This metric makes sure more samples are placed at “inflection points” of models. In other words, more samples are placed in regions where the models are the least stable. In terms of uniformity, each alignment measurement is assumed to be a point charge, and the total energy state of the sample plan is calculated. The total energy formula for N marks may be calculated as:

$${E}_{total} = {\sum }_{i = 1}^{N} {\sum }_{j = i + 1}^{N} \frac{1}{\sqrt{{( {x}_{i} - {x}_{j} )}^{2} + {( {y}_{i} - {y}_{j} )}^{2}}}$$

The least energy state corresponds to the highest uniformity. This metric makes sure that every region on the wafer is properly covered. For edge avoidance, rough rules of thumb can be defined like “avoid sampling outside a radius of 135 mm” to avoid edge region target damage. In scan up/scan down balance, lithography scanners often expose some fields while scanning up and others while scanning down. It is important to measure each roughly the same number of times, so scan direction imbalance metric is introduced.

In some embodiments, the predetermined number includes 10 to 50 of the alignment marks on the wafer. In another embodiment, the predetermined number is user defined. In this manner, the rule based sampling may be performed to generate a sample plan with user defined sample size. For example, while 10 to 50 alignment marks may be a rough estimate of the number of alignment marks that are useful for the applications described herein, the embodiments are not limited to only 10 to 50 alignment marks in the predetermined number. In particular, the embodiments described herein can be used with any predetermined number of alignment marks, which can be user defined based on, for example, how many total alignment marks are on the wafer, throughput requirements, process control requirements, etc.

While the predetermined number of the alignment marks included in the initial sample generated by rule based sampling may vary greatly, it is important that the predetermined number of alignment marks is roughly the same as (or exactly the same as) the preferred number of alignment marks in the sample used in the lithography process. For example, individual alignment marks in the initial sample are examined on a mark-by-mark basis in the data based sampling as described further herein to determine if the mark or one of a relatively small subset of alignment marks proximate the mark should be included in the final sample used in lithography. In this manner, the data based sampling described herein can optimize the marks in the initial sample generated by rule based sampling while also retaining the same number of marks in the final sample output by data based sampling.

For at least one of the alignment marks in the initial sample, selecting the alignment marks for the lithography process includes selecting the at least one of the alignment marks or a different alignment mark in a subset of the alignment marks on the wafer closest to the at least one of the alignment marks by data based sampling of the at least one of the alignment marks and the subset of the alignment marks. In this manner, for each (or at least one) of the alignment marks selected by the rule based sampling, the steps described herein are performed to determine if the alignment mark should be replaced in the final alignment mark sample by one of the alignment marks in the subset. In other words, data based sampling may be performed on a mark-by-mark basis for only the alignment marks in the initial sample generated by rule based sampling, and the marks considered in the data based sampling performed for any one alignment mark in the initial sample is limited to only the subset of alignment marks. The number of alignment marks considered in data based sampling for any one mark may be smaller and even substantially smaller than the number of marks in the initial sample and the total number of marks on the wafer. Data based sampling is therefore performed for a limited number of alignment marks on the wafer (the marks in the initial sample) with a limited number of possible replacement alignment marks for each of the marks in the initial sample. Selecting an alignment mark in the initial sample or replacing it with a neighboring mark may be performed as described further herein.

In one embodiment, the subset of the alignment marks includes the alignment marks in fields on the wafer neighboring a field in which the at least one of the alignment marks is located. In other words, for an alignment mark in the initial sample generated by rule based sampling, the computer system may identify the field in which it is located and then identify any neighboring fields on the wafer. The neighboring fields may be limited to a neighboring field on each side of the alignment mark field in addition to any fields having a corner adjacent to a corner of the alignment mark field. For example, as shown in FIG. 2, for one of the alignment marks in the initial sample whose locations are indicated in wafer map 210 with dots, the subset of alignment marks 212 may include an alignment mark in each of the fields neighboring the field in which the alignment mark is located. The number of alignment marks in a subset for any one of the alignment marks may then vary depending on where on the wafer the alignment mark is located and therefore how many fields are neighboring its field. For example, an alignment mark in a field near the center of the wafer will have more neighboring fields than an alignment mark in a field at one end of a row or column of fields on the wafer.

In another embodiment, the subset of the alignment marks includes only the alignment marks on the wafer in fields neighboring a field in which the at least one of the alignment marks is located for a maximum of 8 of the alignment marks in the subset. In other words, the neighboring fields may be defined as described above as only the fields immediately surrounding the field in which the alignment mark being evaluated is located. In this manner, the alignment marks in a maximum of 8 neighboring fields are evaluated for any one alignment mark in data based sampling. Limiting the number of alignment marks in the subset of marks defined for each alignment mark in the initial sample is important for a few reasons. For example, for sampling optimization, how much the sample plan can change by data based optimization is preferably limited. Therefore, the perturbation window for any one mark in the initial subset may also be limited to +/−1 field in both the X and Y directions.

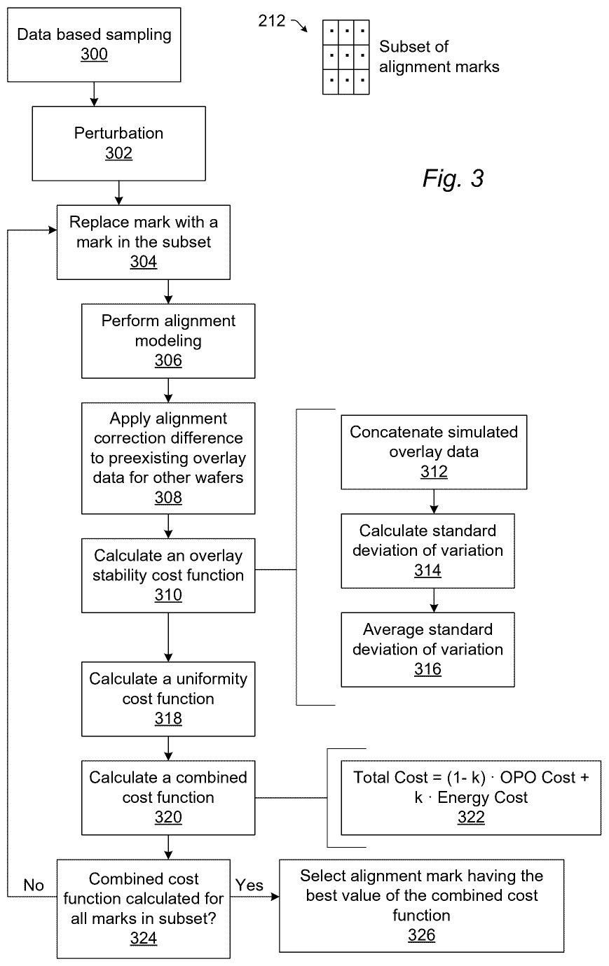

In some embodiments, data based sampling 300 shown in FIG. 3 includes performing perturbation 302 for the at least one of the alignment marks (e.g., the alignment mark in the center of subset 212 of alignment marks) by replacing the at least one of the alignment marks with at least two of the alignment marks in the subset (e.g., any of the other alignment marks in subset 212), as shown in step 304 of FIG. 3, thereby creating at least two different instances of the at least one of the alignment marks. In this manner, for each alignment mark selected by rule based sampling, a perturbation may be performed, which includes replacing the alignment mark with a different alignment mark in a neighboring field. In this manner, for any one alignment mark in the initial sample, the perturbation may be performed with a much lower number of alignment marks than in the currently used data based sampling in which any alignment mark being considered is replaced with every other alignment mark on the wafer. The data based sampling performed by the embodiments described herein for the alignment marks in the initial sample will, therefore, be much faster than previously performed, purely data based alignment mark sampling.

In one such embodiment, the perturbation includes, for the at least one of the alignment marks and each of the at least two different instances, performing alignment modeling as shown in step 306, applying an alignment correction difference to preexisting overlay data for two or more other wafers, as shown in step 308, based on results of the alignment modeling thereby generating simulated overlay data for the two or more other wafers, and calculating an overlay stability cost function as shown in step 310. In this manner, for each mark and each replacement mark being evaluated, the perturbation may include performing alignment modeling, applying the alignment correction difference to the overlay data, and calculating the overlay stability cost function.

Alignment modeling may be performed as follows. From a modeling perspective, both alignment and overlay measurements can be treated as just vector maps on a wafer. Modeling may be performed by least squares regression to solve the linear system of equations A·x=b. A is a MxN regression matrix (M rows for M measurements, N columns for N scanner correction terms), x is the unknown corrections (Nx1) and b is the measurements (Mx1). Using least squares regression, the ideal scanner corrections that will minimize the sum of square of error can be calculated. In one such example, for 10 alignment marks, there would be 10 equations in the X direction and 10 in the Y direction. There may be 4 scanner correctables: Translation in X, Translation in Y, Rotation, and Magnification. Then, A→20x4, x→4x1, and b→20x1.

Alignment modeling performed in this step may also use the same alignment models that are used by lithography scanners. In this manner, the alignment modeling can be optimized for the exact scanner operating conditions. Scanner alignment models can vary widely and just some examples used by commercially available scanners include the following, listed in order of increasing complexity:
4 parameter (translation X, translation Y, rotation, magnification)
6 parameter (translation X, translation Y, rotation, asymmetric rotation, magnification, asymmetric magnification)
high order wafer alignment, 2nd order
high order wafer alignment, 3rd order
high order wafer alignment, 5th order
radial basis function (RBF) alignment

The embodiments described herein may use any of these alignment models in the perturbations described herein. In addition, the embodiments described herein are model independent, meaning that they can work with any existing and future alignment models. In other words, the alignment modeling performed by the embodiments described herein may include any suitable alignment modeling known in the art.

For the optimization described herein, the two or more other wafers preferably include 10+ (i.e., 10 or more) lots of wafers that are already processed and relatively densely measured in the fab (where densely measured may mean all available alignment marks, all available overlay marks). So for each mark, the preexisting overlay data for the two or more other wafers, to which the alignment correction difference is applied based on results of the alignment modeling, preferably includes what alignment data the scanner measured, what corrections it applied, what overlay error was measured, and what feedback corrections were sent back to the scanner. In this manner, when alignment sampling is perturbed in the data based sampling described herein (i.e., moving an alignment mark to one of its 8 neighbors (at most)), exactly how the scanner corrections would change if it had measured that new sample plan can be calculated. How this alignment correction change would impact overlay for each wafer can then be calculated.

In some such embodiments, calculating the overlay stability cost function includes concatenating the simulated overlay data for the two or more other wafers into combined simulated overlay data for a single wafer, as shown in step 312. In this manner, all overlay wafers may be concatenated into a combined wafer. In other words, the simulated overlay data may be generated and gathered as described above and then combined into a single wafer. This concatenation may otherwise be performed in any suitable manner known in the art.

In one embodiment, as shown in step 314, calculating the overlay stability cost function also includes calculating standard deviation of variation in the combined simulated overlay data for each of the at least one of the alignment marks and the at least two different instances on an alignment mark-by-alignment mark basis. In other words, this step may include calculating the standard deviation of variation for every overlay mark in the dataset (mark by mark). The X and Y standard deviation may be calculated at each overlay mark location in the concatenated data. Calculating the standard deviation of variation may otherwise be performed in any suitable manner known in the art.

In another such embodiment, calculating the overlay stability cost function includes calculating an overall stability by averaging the standard deviation of variation for each of the at least one of the alignment marks and the at least two different instances on the alignment mark-by-alignment mark basis, as shown in step 316. In other words, this step may include calculating overall stability by averaging the mark-wise standard deviations. In particular, this step may include averaging mark-wise standard deviation for an overall stability metric. The mark-wise stability is how much wafer-to-wafer overlay variation is observed for each overlay measurement mark location. Averaging the standard deviation of variation may otherwise be performed in any suitable manner known in the art.

In some embodiments, the perturbation also includes, for the at least one of the alignment marks and each of the at least two different instances, calculating a uniformity cost function, as shown in step 318, by performing a total energy calculation based on an assumption that each alignment measurement is a point charge. In this manner, for each case, a total energy calculation may be performed based on a mark charge assumption. This is the uniformity cost function. Performing the total energy calculation may otherwise be performed in any suitable manner known in the art.

In an additional embodiment, the perturbation includes, for the at least one of the alignment marks and each of the at least two different instances, calculating a combined cost function, as shown in step 320, as a weighted average of the overlay stability cost function and the uniformity cost function. Calculating the combined cost function may be performed as described herein.

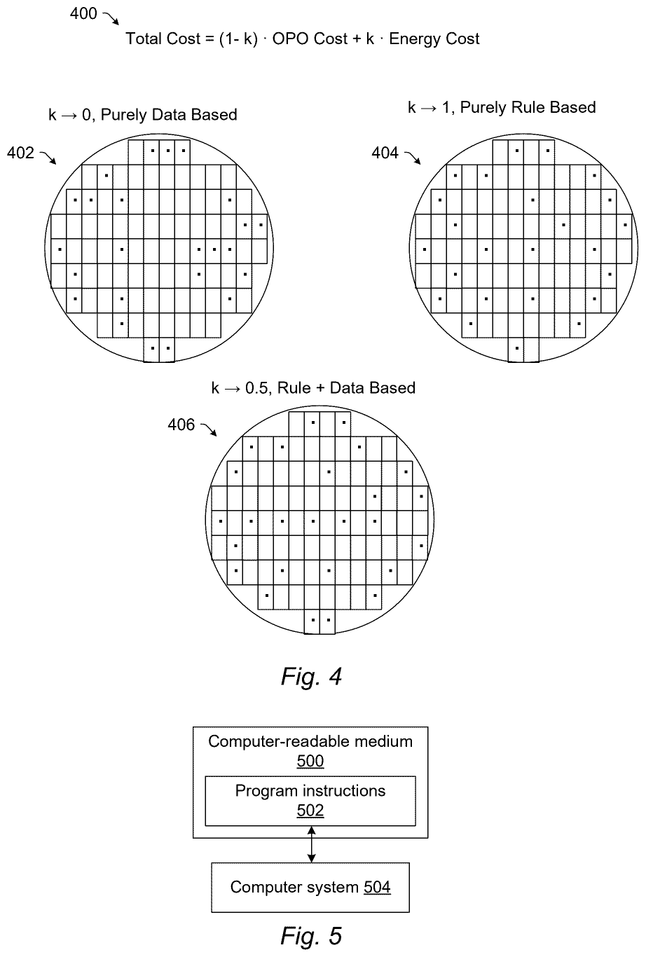

In one embodiment, for the at least one of the alignment marks and each of the at least two different instances, the combined cost function is calculated as total cost function=(1−k)*(overlay stability cost function)+k*(uniformity cost function), as shown in step 322. Therefore, the sampling method may have a weighting parameter “k” to be used in calculating the weighted sum of cost functions. The weighting parameter then determines how the sampling results rely on data based sampling vs. rule based sampling. For example, as shown in FIG. 4, the total cost may be calculated using equation 400, where on-product-overlay (OPO) cost is the overlay stability cost function and energy cost is the uniformity cost function. As k goes to 0, the sampling method becomes purely data based. As k goes to 1, the sampling becomes purely rule based. And as k goes to 0.5, the sampling becomes equally rule and data based.

Wafer maps 402, 404, and 406 shown in FIG. 4 are meant to be non-limiting examples of how the alignment mark sampling for each of the different scenarios described above may vary, with dots in the maps representing locations of alignment marks selected with the hybrid methods described herein. In particular, wafer map 402 shows a non-limiting example of an alignment mark sample generated with purely data based sampling, wafer map 404 shows a non-limiting example of an alignment mark sample generated with purely rule based sampling, and wafer map 406 shows a non-limiting example of an alignment mark sample generated with equally weighted rule and data based sampling. Of course, the selected alignment marks and their locations will vary depending on several factors including locations of the full alignment mark set on the wafer, how many alignment marks are selected by rule based sampling, whether or not alignment marks selected by rule based sampling are replaced with other alignment marks by data based sampling, the value of the weighted parameter, and so on. These maps are only included here to illustrate how different the results can be for different values of the weighted parameter.

In one such embodiment, k is a user tunable parameter responsive to confidence in the preexisting overlay data. In this manner, the user tunable k parameter is a measure of how confident a user is of the data at hand. For example, if there is long term data that is believed to be representative of all the possible process variations that can occur in high volume manufacturing (HVM), k can be set to 0 to perform a purely data based enhancement to result in best overlay. On the other hand, if there is relatively limited data that does not paint a full picture of possible process variations, k may be kept close to 1 to not deviate from the uniform sample plan too much, which should be safer for unforeseen process signatures. Note, setting k=1 basically converts this approach to a rule based sampling approach.

After a combined cost function has been determined for one of the alignment marks in a subset, the perturbation may include determining if the combined cost function has been calculated for all of the marks in the subset, as shown in step 324. Step 324 may alternatively include determining if the combined cost function has been calculated for all of the marks in the subset for which the perturbation is to be performed, which may be the case when not all of the marks in the subset are being considered for sampling. When step 324 determines that a combined cost function has not been determined for all marks in the subset (or being used for perturbation), the perturbation may include returning to step 304 and replacing the alignment mark in the initial sample with the next alignment mark in the subset (or a remaining mark in the subset selected for perturbation).

When step 324 determines that a combined cost function has been determined for all of the marks in the subset (or all of the marks in the subset selected for perturbation), the alignment mark sampling may proceed to step 326. In some embodiments, as shown in step 326, the data based sampling includes selecting one of the at least one of the alignment marks and the at least two different instances having a best value of the combined cost function as one of the selected alignment marks for use in the alignment of the wafer. For example, if the alignment mark selected by rule based sampling does not have the best combined cost function, the rule based selected alignment mark may be replaced with a neighboring mark that results in the best combined cost function. In this manner, for each mark in the rule based sample, the mark or a different mark in a neighboring field having the best combined cost function value may be selected for use in the lithography process. In this manner, each alignment mark in the initial sample may be selected or replaced based on combined cost function.

The optimization may be ended when each alignment mark has been perturbed and optimized.

Although some particularly advantageous ways of calculating and using the combined cost function for optimization are described above, these calculations can be modified in a few ways while still providing the same (or nearly the same) optimization results. For example, the perturbation may include replacing an alignment mark in the initial sample with one of its neighboring marks in a neighboring field, and evaluating the simulated overlay stability cost function for each case. These steps may be performed as described herein.

The test average signature may then be removed from the simulated overlay stability cost function and a mean+3sigma (M+3S) metric may be calculated. The M+3S metric may be normalized by dividing it with the maximum M+3S obtained. The test average signature means that all simulated wafer data is combined and the average of all data is calculated. For example, there may be 300 measured points on a wafer and 10 wafers in the simulation, which means that a combined wafer with 300×10=3000 points may be created. Then for each point, 10 simulated overlay data may be averaged to generate a 300 point wafer map that is the test average signature. When this signature is removed from the data, only the variation remains (zero mean for each test).

A two-dimensional (2D) energy metric (also referred to herein as total energy metric) may be calculated as described herein and normalized by dividing it with the maximum 2D energy obtained. The alignment target selected from any one subset may then be the one that gives the minimum weighted sum of M+3S metric and 2D energy.

The embodiments described herein have a number of important, new features that provide significant improvements over the currently used methods and systems for alignment mark sampling. One such new feature is combining rule based and data based approaches in a sequential fashion. Another such new feature is performing “constrained” data based optimization by anchoring it with the rule based sample plan. An additional new feature is calculating an overlay stability metric based on alignment sample plan changes. Yet another new feature is calculating a combined cost function that is both data and rule based, which is tunable based on the size of the optimization dataset.

The embodiments described herein have, therefore, a number of important differences from the currently used alignment mark sampling methods and systems that provide a number of important advantages and improvements over those previously used methods and systems. For example, the embodiments described herein rely on rule based sampling to initialize optimization, which gets much closer to the optimal point so the initial “hunting to target” phase of the data based sampling is highly accelerated.

The embodiments described herein also enhance the rule based sample plan with data based metrics, so the optimization is not blind to process related alignment target damage anymore. In addition, the embodiments described herein make sure the solution is still anchored by the rule based sample plan, because each target can deviate at most one field from the rule based sample plan. Therefore, the embodiments described herein avoid the overoptimization problem of purely data based sampling. Furthermore, the embodiments described herein perform only one pass of perturbation for each target and only to the neighboring fields, so it drastically reduces the optimization domain and number of data based iterations, making the embodiments faster.

Moreover, the embodiments described herein use a cross-domain alignment optimization metric that is based on overlay, which is the ultimate metric that is tied to yield. Alignment effects on overlay are widely simulated, but not used within alignment optimization methods and systems due to performance reasons. The embodiments described herein replace the full alignment and overlay APC system simulations with a simpler overlay stability metric. In this manner, the embodiments described herein do not have to perform the full APC simulation and can use this metric within optimization.

Some alternate methods and systems for alignment mark sampling were also considered in developing the embodiments described herein. For example, the inventors explored performing prefiltering of data before running either data or rule based sampling optimization. In one such example, alignment marks with relatively low quality metrics may be removed from optimization. This approach may be beneficial but does not match the performance of the embodiments described herein.

The inventors also explored manually altering optimized sampling plans. This approach was examined to provide proof of the concept for the embodiments described herein. In this experiment, an HVM alignment sample plan was acquired and some alignment marks in regions of relatively high overlay misregistration were manually moved to neighboring alignment marks, and the resultant overlay was simulated to provide improvements. Although this is a substantially tedious and infeasible approach, it did provide proof of concept for the more formalized and automated version of this approach embodied in the systems and methods described herein.

Selecting the alignment marks on the wafer for the lithography process also includes storing information for the selected at least one of the alignment marks or the selected different alignment mark in information for the selected alignment marks on the wafer for use in the alignment of the wafer to the mask during the lithography process. Storing the information for the selected alignment marks may be performed as described further herein. In this manner, the stored information may be accessed, retrieved, acquired etc. by a lithography tool as described herein and used to perform alignment with the sampled alignment marks on one or more wafers. For example, the alignment sampling described herein may be performed once per layer, and every lot/wafer would be run with the optimized sample plan described herein. Optimization may be repeated after a modification to the lithography process, like a preventative maintenance event that might change alignment/overlay signatures drastically. Optimization may also be repeated as often as selected by a user or in any other manner.

All of the embodiments described herein may include storing results of one or more steps of the embodiments in a computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc.

As described herein, the embodiments may be configured for sampling one or more alignment marks for a lithography process performed by a scanner. In some embodiments, the computer system is configured for storing information for the sampled alignment marks for the next steps of the process setup and/or for use in any of the processes described herein. The computer system may be configured to store the information in a recipe or by generating a recipe for the process in which the sampled alignment marks will be used. A “recipe” as that term is used herein can be generally defined as a set of instructions that can be used by a tool to perform a process on a specimen. In this manner, generating a recipe may include generating information for how a process is to be performed, which can then be used to generate the instructions for performing that process. The information for the sampled alignment marks that is stored by the computer system may include any information that can be used to identify and/or use the sampled alignment marks (e.g., such as a file name and where it is stored, and the file may include information for the sampled alignment marks such as alignment mark names, alignment mark locations, etc.).

The information for the sampled alignment marks and/or the recipe may then be used by the system or method (or another system or method) to perform one or more processes on the wafer, e.g., wafer alignment, to thereby align the wafer to the mask in the lithography process. The information generated by alignment performed with the sampled alignment marks may include, for example, results for any alignment measurements 104 shown in FIG. 1. The information generated for the sampled alignment marks may also include overlay measurements 112 performed as described herein, which may provide feedback to APC system 116 on how well alignment is being performed with the sampled alignment marks. The results of the alignment and/or overlay measurements may be generated by the computer system and/or the system shown in FIG. 1 in any suitable manner. These results may have any suitable form or format such as a standard file type. The computer system and/or the system shown in FIG. 1 may generate the results and store the results such that the results can be used by the computer system and/or another system or method to perform one or more functions for the wafer including, but not limited to, feedforward corrections 106 and feedback corrections 118.

In this manner, the information for the sampled alignment marks generated by the sampling described herein and/or during use of the sampled alignment marks may be used for altering a process such as a fabrication process or step that was or will be performed on the wafer in a feedback or feedforward manner. In one embodiment, the computer system is configured for altering one or more parameters of a process tool used to perform a process on the wafer based on results of one or more steps described herein. The changes to the process may include any suitable changes to one or more parameters of the process. The computer system preferably determines those changes such that the alignment marks can be used during a lithography process to provide better alignment of the wafer to the mask and/or better feedback and/or feedforward corrections generated based on the alignment and/or overlay measurements described herein. The computer system may determine such changes in any suitable manner known in the art.

Those changes can then be sent to a semiconductor fabrication system (e.g., scanner 102) or a storage medium (not shown) accessible to the computer system and the semiconductor fabrication system. The semiconductor fabrication system may or may not be part of the system embodiments described herein. For example, the computer system described herein may be coupled to the semiconductor fabrication system, e.g., via one or more common elements such as a housing, a power supply, a specimen handling device or mechanism, etc.

Each of the embodiments of each of the systems described above may be combined together into one single embodiment.

Another embodiment relates to a computer-implemented method for determining information for alignment marks on a wafer for use in a lithography process. The method includes selecting alignment marks on a wafer for alignment of the wafer to a mask during a lithography process. The selecting includes generating an initial sample of a predetermined number of alignment marks by rule based sampling of the alignment marks on the wafer. For at least one of the alignment marks in the initial sample, the selecting includes selecting the at least one of the alignment marks or a different alignment mark in a subset of the alignment marks on the wafer closest to the at least one of the alignment marks by data based sampling of the at least one of the alignment marks and the subset of the alignment marks. In addition, the selecting includes storing information for the selected at least one of the alignment marks or the selected different alignment mark in information for the selected alignment marks on the wafer for use in the alignment of the wafer to the mask during the lithography process. The selecting is performed by a computer system.

Each of the steps of the method may be performed as described further herein. The method may also include any other step(s) that can be performed by the system and/or computer system described herein, which may be configured according to any of the embodiments described herein. In addition, the method described above may be performed by any of the system embodiments described herein.

An additional embodiment relates to a non-transitory computer-readable medium storing program instructions executable on a computer system for performing a computer-implemented method for determining information for alignment marks on a wafer for use in a lithography process. One such embodiment is shown in FIG. 5. In particular, as shown in FIG. 5, non-transitory computer-readable medium 500 includes program instructions 502 executable on computer system 504. The computer-implemented method may include any step(s) of any method(s) described herein.

Program instructions 502 implementing methods such as those described herein may be stored on computer-readable medium 500. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system 504 may be configured according to any of the embodiments described herein.

Further modifications and alternative embodiments of various aspects of the invention will be apparent to those skilled in the art in view of this description. For example, methods and systems for determining information for alignment marks on a wafer for use in a lithography process are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for determining information for alignment marks on a wafer for use in a lithography process, comprising:
a computer system configured for selecting alignment marks on a wafer for alignment of the wafer to a mask during a lithography process, wherein said selecting comprises:
generating an initial sample of a predetermined number of alignment marks by rule based sampling of the alignment marks on the wafer;
for at least one of the alignment marks in the initial sample, selecting the at least one of the alignment marks or a different alignment mark in a subset of the alignment marks on the wafer closest to the at least one of the alignment marks by data based sampling of the at least one of the alignment marks and the subset of the alignment marks; and
storing information for the selected at least one of the alignment marks or the selected different alignment mark in information for the selected alignment marks on the wafer for use in the alignment of the wafer to the mask during the lithography process.

2. The system of claim 1, wherein input to the rule based sampling does not comprise data for the alignment marks on the wafer generated by a tool that performed a process on the wafer, and wherein input to the data based sampling comprises the data.

3. The system of claim 1, wherein the rule based sampling generates the initial sample for a predetermined alignment model and a definition of a full map of the alignment marks on the wafer.

4. The system of claim 1, wherein the rule based sampling is performed with a heuristic function comprising a weighted combination of multiple cost functions.

5. The system of claim 1, wherein the predetermined number comprises 10 to 50 of the alignment marks on the wafer.

6. The system of claim 1, wherein the predetermined number is user defined.

7. The system of claim 1, wherein the subset of the alignment marks comprises the alignment marks in fields on the wafer neighboring a field in which the at least one of the alignment marks is located.

8. The system of claim 1, wherein the subset of the alignment marks comprises only the alignment marks on the wafer in fields neighboring a field in which the at least one of the alignment marks is located for a maximum of 8 of the alignment marks in the subset.

9. The system of claim 1, wherein the data based sampling comprises performing a perturbation for the at least one of the alignment marks by replacing the at least one of the alignment marks with at least two of the alignment marks in the subset thereby creating at least two different instances of the at least one of the alignment marks.

10. The system of claim 9, wherein the perturbation comprises, for the at least one of the alignment marks and each of the at least two different instances, performing alignment modeling, applying an alignment correction difference to preexisting overlay data for two or more other wafers based on results of the alignment modeling thereby generating simulated overlay data for the two or more other wafers, and calculating an overlay stability cost function.

11. The system of claim 10, wherein calculating the overlay stability cost function comprises concatenating the simulated overlay data for the two or more other wafers into combined simulated overlay data for a single wafer.

12. The system of claim 11, wherein calculating the overlay stability cost function further comprises calculating standard deviation of variation in the combined simulated overlay data for each of the at least one of the alignment marks and the at least two different instances on an alignment mark-by-alignment mark basis.

13. The system of claim 12, wherein calculating the overlay stability cost function further comprises calculating an overall stability by averaging the standard deviation of variation for each of the at least one of the alignment marks and the at least two different instances on the alignment mark-by-alignment mark basis.

14. The system of claim 10, wherein the perturbation further comprises, for the at least one of the alignment marks and each of the at least two different instances, calculating a uniformity cost function by performing a total energy calculation based on an assumption that each alignment measurement is a point charge.

15. The system of claim 14, wherein the perturbation further comprises, for the at least one of the alignment marks and each of the at least two different instances, calculating a combined cost function as a weighted average of the overlay stability cost function and the uniformity cost function.

16. The system of claim 15, wherein the data based sampling further comprises selecting one of the at least one of the alignment marks and the at least two different instances having a best value of the combined cost function as one of the selected alignment marks for use in the alignment of the wafer.

17. The system of claim 15, wherein, for the at least one of the alignment marks and each of the at least two different instances, the combined cost function is calculated as total cost function=(1−k)*(overlay stability cost function)+k*(uniformity cost function).

18. The system of claim 17, wherein k is a user tunable parameter responsive to confidence in the preexisting overlay data.

19. A non-transitory computer-readable medium, storing program instructions executable on a computer system for performing a computer-implemented method for determining information for alignment marks on a wafer for use in a lithography process, wherein the computer-implemented method comprises:
selecting alignment marks on a wafer for alignment of the wafer to a mask during a lithography process, wherein said selecting comprises:
generating an initial sample of a predetermined number of alignment marks by rule based sampling of the alignment marks on the wafer;
for at least one of the alignment marks in the initial sample, selecting the at least one of the alignment marks or a different alignment mark in a subset of the alignment marks on the wafer closest to the at least one of the alignment marks by data based sampling of the at least one of the alignment marks and the subset of the alignment marks; and
storing information for the selected at least one of the alignment marks or the selected different alignment mark in information for the selected alignment marks on the wafer for use in the alignment of the wafer to the mask during the lithography process.

20. A computer-implemented method for determining information for alignment marks on a wafer for use in a lithography process, comprising:
selecting alignment marks on a wafer for alignment of the wafer to a mask during a lithography process, wherein said selecting comprises:
generating an initial sample of a predetermined number of alignment marks by rule based sampling of the alignment marks on the wafer;
for at least one of the alignment marks in the initial sample, selecting the at least one of the alignment marks or a different alignment mark in a subset of the alignment marks on the wafer closest to the at least one of the alignment marks by data based sampling of the at least one of the alignment marks and the subset of the alignment marks; and
storing information for the selected at least one of the alignment marks or the selected different alignment mark in information for the selected alignment marks on the wafer for use in the alignment of the wafer to the mask during the lithography process, wherein the selecting is performed by a computer system.
